(19) United States
(12) Patent Application Publication
(10) Pub. No.: US 2026/0168080 A1
(43) Pub. Date: Jun. 18, 2026

(54) APPARATUS FOR DEPOSITING TRANSITION METAL DICHALCOGENIDE THIN FILM

(71) Applicant: SAMSUNG ELECTRONICS CO., LTD., Suwon-si (KR)

(72) Inventors: Seung Jun LEE, Suwon-si (KR); Min Woo PARK, Suwon-si (KR); Hyung-Jung YONG, Suwon-si (KR); Seong June JEONG, Suwon-si (KR); Han Byul KANG, Suwon-si (KR); Jae Ho KIM, Suwon-si (KR); Eun Kyu LEE, Suwon-si (KR)

(73) Assignee: SAMSUNG ELECTRONICS CO., LTD., Suwon-si (KR)

(21) Appl. No.: 19/189,731

(22) Filed: Apr. 25, 2025

(30) Foreign Application Priority Data
Dec. 17, 2024 (KR) 10-2024-0187876

(51) Int. Cl. C23C 14/24; C23C 14/06; C23C 14/50; C23C 14/54

(52) U.S. Cl. CPC C23C 14/24; C23C 14/0623; C23C 14/50; C23C 14/541; C23C 14/542

(57) ABSTRACT

An apparatus for depositing a transition metal dichalcogenide (TMD) thin film according to some embodiments of the present disclosure is provided. The apparatus for depositing a TMD thin film includes a deposition chamber in which a vacuum is formed; a heater which is disposed inside the deposition chamber and which supports and heats a substrate on which a TMD thin film is deposited; a precursor supply assembly which supplies a TMD precursor to the deposition chamber; a reactant supply assembly which supplies a reactant for synthesizing the TMD thin film together with the TMD precursor to the deposition chamber; and a deposition controller which controls the deposition chamber, the heater, the precursor supply assembly, and the reactant supply assembly, wherein the deposition controller controls the heater so that a temperature of the substrate becomes 250° C. or more and less than 500° C.

### CROSS-REFERENCE TO RELATED APPLICATION

This application claims priority from Korean Patent Application Nos. 10-2024-0187876 filed on Dec. 17, 2024 in the Korean Intellectual Property Office and all the benefits accruing therefrom under 35 U.S.C. 119, the contents of which in its entirety are herein incorporated by reference.

### BACKGROUND

### 1. Technical Field

The present disclosure relates to an apparatus for depositing a transition metal dichalcogenide (TMD) thin film.

### 2. Description of Related Art

A TMD (Transition Metal Dichalcogenide) is a two-dimensional semiconductor material which is a combination of transition metal and chalcogen and has a band gap. The TMD has an atomic layered structure in which molecules or atoms are bound only two-dimensionally, and is a crystalline layered structure in which each layer is bound by Van der Waals force.

Since the TMD has the band gap as described above, a TMD thin film may be deposited on a substrate such as a wafer to fabricate a semiconductor element such as a FET (Field Effect Transistor). Since the TMD thin film is a two-dimensional semiconductor material, the semiconductor element including the TMD thin film is very small and thin.

In the related art, in order to deposit the TMD thin film on the substrate, a heater is disposed inside a chamber in which a vacuum is formed, and the substrate is disposed on the heater. Further, in a state in which the heater heats the substrate to a temperature higher than 800° C., a TMD precursor and a reactant that synthesizes the TMD thin film together with the TMD precursor are simultaneously supplied to a deposition chamber.

When the TMD precursor and the reactant are simultaneously supplied to the deposition chamber, particles may be generated on a surface of the TMD thin film due to a gas phase nucleation reaction between the TMD precursor and the reactant. Such particles of the TMD thin film may be visually checked and affect subsequent processes.

In addition, when the heater heats the substrate to a temperature higher than 800° C., a vacancy may be generated in the TMD thin film deposited on the substrate. When a vacancy is formed in the TMD thin film, the electrical characteristics of the TMD thin film are degraded, and the characteristics of the semiconductor element including the TMD thin film are degraded.

When the temperature of the substrate is lowered to prevent this, the crystallinity of the TMD thin film is degraded, a TMD thin film of a layered structure cannot be secured, and the characteristics of the semiconductor device including the TMD thin film are degraded.

In addition, when a catalyst is used for temperature compensation, catalyst impurities may remain in the TMD thin film.

### SUMMARY

Aspects of the present disclosure provide an apparatus for depositing a TMD thin film capable of depositing a TMD thin film having a crystalline layered structure on a substrate without side effects such as particles and vacancies at a temperature of less than 500° C.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

An apparatus for depositing a transition metal dichalcogenide (TMD) thin film according to some embodiments of the present disclosure is provided. The apparatus for depositing a TMD thin film comprises a deposition chamber in which a vacuum is formed; a heater which is disposed inside the deposition chamber and which supports and heats a substrate on which a TMD thin film is deposited; a precursor supply assembly which supplies a TMD precursor to the deposition chamber; a reactant supply assembly which supplies a reactant for synthesizing the TMD thin film together with the TMD precursor to the deposition chamber; and a deposition controller which controls the deposition chamber, the heater, the precursor supply assembly, and the reactant supply assembly, wherein the deposition controller controls the heater so that a temperature of the substrate becomes 250° C. or more and less than 500° C., the deposition controller controls the precursor supply assembly and the reactant supply assembly so that the TMD precursor and the reactant are alternately supplied to the deposition chamber, and a precursor supply time, which is a time during which the TMD precursor is supplied to the deposition chamber, and a reactant supply time, which is a time during which the reactant is supplied to the deposition chamber, are each 10 seconds or more.

An apparatus for depositing a TMD thin film according to some embodiments of the present disclosure is provided. The apparatus for depositing a TMD thin film comprises a deposition chamber in which a vacuum is formed; a heater which is disposed inside the deposition chamber and which supports and heats a substrate on which a TMD thin film is deposited; a precursor supply assembly which supplies a TMD precursor to the deposition chamber; a reactant supply assembly which supplies a reactant for synthesizing the TMD thin film together with the TMD precursor to the deposition chamber; and a deposition controller which controls the deposition chamber, the heater, the precursor supply assembly, and the reactant supply assembly, wherein the deposition controller controls the heater so that a temperature of the substrate becomes 250° C. or more and less than 500° C., the deposition controller controls the precursor supply assembly and the reactant supply assembly so that the TMD precursor and the reactant are alternately supplied to the deposition chamber, a precursor supply time, which is a time during which the TMD precursor is supplied to the deposition chamber, and a reactant supply time, which is a time during which the reactant is supplied to the deposition chamber, are each 10 seconds or more, the substrate is pretreated with a pretreatment gas in a plasma state before the TMD thin film is deposited, and a plasma generator which turns the pretreatment gas into a plasma and is controlled by the deposition controller is disposed in or connected to the deposition chamber.

An apparatus for depositing a TMD thin film according to some embodiments of the present disclosure is provided. The apparatus for depositing a TMD thin film comprises a pretreatment assembly which pretreats a substrate; and a deposition assembly which deposits a TMD thin film on the substrate pretreated in the pretreatment assembly, wherein the pretreatment assembly includes: a pretreatment chamber in which a vacuum is formed; a substrate support which is disposed inside the pretreatment chamber and supports the substrate to be pretreated; and a pretreatment controller that controls the pretreatment chamber and the substrate support, wherein the substrate is pretreated with a pretreatment gas in a plasma state, and a plasma generator that turns the pretreatment gas into plasma and is controlled by the pretreatment controller is disposed in or connected to the pretreatment chamber, wherein the deposition assembly includes: a deposition chamber in which a vacuum is formed; a heater which is disposed inside the deposition chamber and which supports and heats a substrate on which the TMD thin film is deposited; a precursor supply assembly which supplies a TMD precursor to the deposition chamber; a reactant supply assembly which supplies a reactant for synthesizing the TMD thin film together with the TMD precursor to the deposition chamber; and a deposition controller which controls the deposition chamber, the heater, the precursor supply assembly, and the reactant supply assembly, wherein the deposition controller controls the heater so that a temperature of the substrate becomes 250° C. or more and less than 500° C., the deposition controller controls the precursor supply assembly and the reactant supply assembly so that the TMD precursor and the reactant are alternately supplied to the deposition chamber, and a precursor supply time, which is a time during which the TMD precursor is supplied to the deposition chamber, and a reactant supply time, which is a time during which the reactant is supplied to the deposition chamber, are each 10 seconds or more.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is diagram showing an apparatus for depositing a TMD thin film according to some embodiments of the present disclosure.

FIG. 2 is a graph showing a state in which the TMD precursor and the reactant are supplied to the deposition chamber according to the process time in the apparatus for depositing the TMD thin film of FIG. 1.

FIG. 3 is a diagram showing the supply of the TMD precursor to the deposition chamber in the apparatus for depositing a TMD thin film of FIG. 1.

FIG. 4 is a diagram showing the process of purging the interior of the deposition chamber with a purge gas after the TMD precursor is supplied to the deposition chamber in the apparatus for depositing a TMD thin film of FIG. 1.

FIG. 5 is a diagram showing the supply of reactants to the deposition chamber in the apparatus for depositing a TMD thin film of FIG. 1.

FIG. 6 is a diagram showing purging of the interior of the deposition chamber with a purge gas after supplying the reactants to the deposition chamber in the apparatus for depositing a TMD thin film of FIG. 1.

FIG. 7 is a transmission electron microscope (TEM) photograph of a cross section of an example of a TMD thin film deposited on the substrate by the apparatus for depositing a TMD thin film of FIG. 1.

FIG. 8 is a graph showing results of Raman analysis of an example of the TMD thin film deposited on the substrate W by the apparatus for depositing a TMD thin film of FIG. 1.

FIG. 9 is a scanning electron microscope (SEM) photograph of an example of the TMD thin film deposited on the substrate by the apparatus for depositing the TMD thin film of FIG. 1.

FIG. 10 is an X-ray photoelectron spectroscopy graph of an example of the TMD thin film deposited on the substrate W by the apparatus for depositing a TMD thin film of FIG. 1, and an X-ray photoelectron spectroscopy graph of molybdenum disulfide crystal (MoS₂ Crystal).

FIG. 11 is a table showing a ratio of molybdenum and sulfur of an example of the TMD thin film deposited on the substrate by the apparatus for depositing the TMD thin film of FIG. 1 and a ratio of molybdenum and sulfur of the molybdenum disulfide crystal (MoS₂ Crystal).

FIG. 12 is a diagram showing the apparatus for depositing the TMD thin film according to some embodiments of the present disclosure.

FIG. 13 is a diagram showing the pretreatment of a substrate in the apparatus for depositing the TMD thin film of FIG. 12.

FIG. 14 is a diagram showing an apparatus for depositing a TMD thin film according to some embodiments of the present disclosure.

### DETAILED DESCRIPTION

Although terms such as first, second, upper, and lower are used herein to describe various elements or components, these elements or components are not limited by the terms. Rather, the terms are merely used herein to distinguish one element or component from another element or component. Therefore, a first element or component as mentioned below may also be a second element or component within the technical spirit of the present disclosure. Further, a lower element or component as mentioned below may also be an upper element or component within the technical spirit of the present disclosure.

Hereinafter, embodiments of the present disclosure are described in detail with reference to the attached drawings. The same reference numerals are used for the same components in the drawings, and duplicate descriptions thereof are omitted.

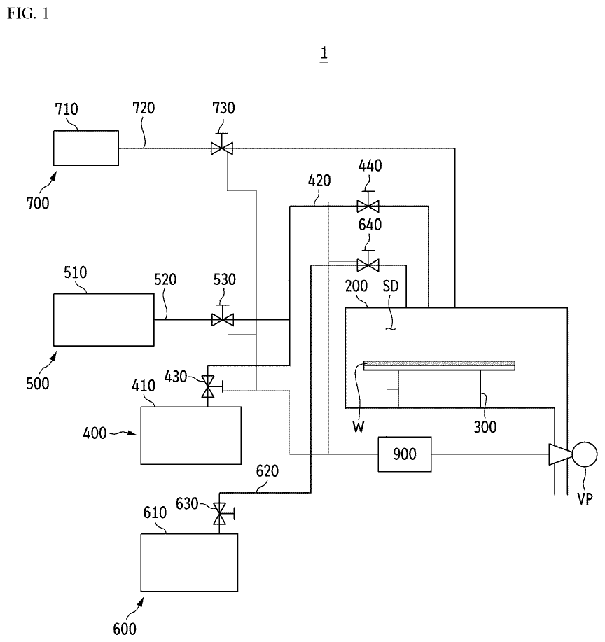

FIG. 1 is diagram showing an apparatus for depositing a TMD thin film according to some embodiments of the present disclosure.

Referring to FIG. 1, an apparatus 1 for depositing the TMD thin film may deposit a TMD (Transition Metal Dichalcogenide) thin film on a substrate W such as a wafer. The apparatus 1 for depositing the TMD thin film may deposit the TMD thin film on one side of the substrate W. For example, the apparatus 1 for depositing the TMD thin film may deposit the TMD thin film on the upper side of the substrate W. The apparatus 1 for depositing the TMD thin film includes a deposition chamber 200, a heater 300, a precursor supply assembly 400, a carrier gas supply assembly 500, a reactant supply assembly 600, a purge gas supply assembly 700, a deposition controller 900, etc.

The deposition chamber 200 may provide a space in which a TMD thin film is deposited on the substrate W. A deposition space SD is formed inside the deposition chamber 200, and the TMD thin film may be deposited on the substrate W in the deposition space SD.

A vacuum may be formed inside the deposition chamber 200. In other words, the deposition space SD of the deposition chamber 200 may be a vacuum. The deposition chamber 200 may be connected to a vacuum pump VP so that a vacuum is formed inside the deposition chamber 200. The vacuum pump VP may be connected to the deposition chamber 200 to communicate with the deposition space SD of the deposition chamber 200. The vacuum pump VP discharges gases and the like of the deposition space SD to the outside of the deposition chamber 200, and the deposition space SD may become a vacuum. The vacuum pump VP is connected to the deposition controller 900, and may be controlled by the deposition controller 900.

A gate (not shown) is formed in the deposition chamber 200, and the substrate W may enter and exit the deposition space SD of the deposition chamber 200 through the gate. A shower head (not shown) connected to the precursor supply assembly 400, the reactant supply assembly 600, and the purge gas supply assembly 700 may be disposed in the deposition chamber 200. The TMD precursor and carrier gas to be described below supplied through the precursor supply assembly 400 and the carrier gas supply assembly 500, the reactant to be described below supplied through the reactant supply assembly 600, or the purge gas to be described below supplied through the purge gas supply assembly 700 may be evenly supplied to the deposition chamber 200 through the shower head.

The heater 300 may heat the substrate W. The heater 300 may also support the substrate W on which the TMD thin film is deposited. In other words, the heater 300 may heat the substrate W while supporting the substrate W. The heater 300 may be disposed inside the deposition chamber 200. The heater 300 may be disposed in the deposition space SD of the deposition chamber 200. The heater 300 is connected to the deposition controller 900 and may be controlled by the deposition controller 900.

The precursor supply assembly 400 may supply the TMD precursor to the deposition chamber 200. The precursor supply assembly 400 may supply the TMD precursor to the deposition space SD of the deposition chamber 200. The TMD precursor may be a combination of a transition metal and organic matter such as an organic ligand. For example, the TMD precursor may be molybdenum hexacarbonyl (Mo(CO)₆). However, the TMD precursor is not limited thereto. The precursor supply assembly 400 is connected to the deposition controller 900 and may be controlled by the deposition controller 900. The precursor supply assembly 400 includes a precursor supply source 410, a precursor supply pipe 420, a first precursor supply valve 430, a second precursor supply valve 440, etc.

The precursor supply source 410 may store the TMD precursor. The precursor supply source 410 may be a storage container, a storage tank or the like in which the TMD precursor is stored. However, the precursor supply source 410 is not limited thereto.

The precursor supply pipe 420 may provide a passage through which the TMD precursor of the precursor supply source 410 is supplied to the deposition chamber 200. In other words, the TMD precursor of the precursor supply source 410 may flow through the precursor supply pipe 420 and be supplied to the deposition chamber 200. The precursor supply pipe 420 may be connected to the precursor supply source 410 and the deposition chamber 200.

The first precursor supply valve 430 may be opened or closed so that the TMD precursor of the precursor supply source 410 flows or does not flow to the precursor supply pipe 420. Furthermore, the flow rate of the TMD precursor flowing from the precursor supply source 410 to the precursor supply pipe 420 may be adjusted by the first precursor supply valve 430. The first precursor supply valve 430 may be disposed in the precursor supply pipe 420 to be adjacent to the precursor supply source 410. The first precursor supply valve 430 is connected to the deposition controller 900 and may be controlled by the deposition controller 900.

The second precursor supply valve 440 may be opened or closed so that the TMD precursor flowing through the precursor supply pipe 420 is supplied or not supplied to the deposition chamber 200. The second precursor supply valve 440 may be disposed in the precursor supply pipe 420 to be adjacent to the deposition chamber 200. The second precursor supply valve 440 is connected to the deposition controller 900 and may be controlled by the deposition controller 900.

The carrier gas supply assembly 500 may supply the precursor supply assembly 400 with a carrier gas which carries the TMD precursor to the deposition chamber 200. The carrier gas supplied to the precursor supply assembly 400 may be mixed with the TMD precursor and flow into the deposition chamber 200 together with the TMD precursor to carry the TMD precursor to the deposition chamber 200. The carrier gas may be an inert gas. For example, the carrier gas may be argon (Ar) gas. However, the carrier gas is not limited thereto. The carrier gas supply assembly 500 is connected to the deposition controller 900 and may be controlled by the deposition controller 900. The carrier gas supply assembly 500 includes a carrier gas supply source 510, a carrier gas supply pipe 520, a carrier gas supply valve 530, etc.

The carrier gas supply source 510 may store the carrier gas. The carrier gas supply source 510 may be a storage container, a storage tank or the like in which the carrier gas is stored. However, the carrier gas supply source 510 is not limited thereto.

The carrier gas supply pipe 520 may provide a passage through which the carrier gas of the carrier gas supply source 510 is supplied to the precursor supply assembly 400. In other words, the carrier gas of the carrier gas supply source 510 may flow through the carrier gas supply pipe 520 and be supplied to the precursor supply assembly 400. The carrier gas supply pipe 520 may be connected to the carrier gas supply source 510 and the precursor supply pipe 420 of the precursor supply assembly 400. In this manner, because the carrier gas supply pipe 520 is connected to the precursor supply pipe 420, and the carrier gas is directly supplied to the TMD precursor flowing through the precursor supply pipe 420, it may be advantageous for controlling the concentration of the TMD precursor. In addition, the TMD precursor may be supplied to the deposition chamber 200 at a low concentration. The carrier gas supply pipe 520 may be connected to the precursor supply pipe 420 between the first precursor supply valve 430 and the second precursor supply valve 440.

The carrier gas supply valve 530 may be opened or closed so that the carrier gas of the carrier gas supply source 510 flows or does not flow to the carrier gas supply pipe 520. Furthermore, the flow rate of the carrier gas flowing from the carrier gas supply source 510 to the carrier gas supply pipe 520 may be adjusted by the carrier gas supply valve 530. The carrier gas supply valve 530 may be disposed in the carrier gas supply pipe 520 to be adjacent to the carrier gas supply source 510. The carrier gas supply valve 530 is connected to the deposition controller 900 and may be controlled by the deposition controller 900.

The reactant supply assembly 600 may supply reactants to the deposition chamber 200 for synthesizing the TMD thin film together with the TMD precursor. The reactant supply assembly 600 may supply reactants to the deposition space SD of the deposition chamber 200. The reactant may be a combination of chalcogen and organic matter such as an organic ligand. For example, the reactant may be diethyl sulfide ((C₂H₅)₂S). However, the reactant is not limited thereto. The reactant supply assembly 600 is connected to the deposition controller 900 and may be controlled by the deposition controller 900. The reactant supply assembly 600 includes a reactant supply source 610, a reactant supply pipe 620, a first reactant supply valve 630, a second reactant supply valve 640, etc.

The reactant source 610 may store the reactant. The reactant supply source 610 may be a storage container, a storage tank or the like in which the reactant is stored. However, the reactant source 610 is not limited thereto.

The reactant supply pipe 620 may provide a passage through which the reactant of the reactant source 610 is supplied to the deposition chamber 200. In other words, the reactant of the reactant source 610 may flow through the reactant supply pipe 620 and be supplied to the deposition chamber 200. The reactant supply pipe 620 may be connected to the reactant source 610 and the deposition chamber 200.

The first reactant supply valve 630 may be opened or closed so that the reactant of the reactant source 610 flows or does not flow to the reactant supply pipe 620. Furthermore, the flow rate of the reactant flowing from the reactant source 610 to the reactant supply pipe 620 may be adjusted by the first reactant supply valve 630. The first reactant supply valve 630 may be disposed in the reactant supply pipe 620 to be adjacent to the reactant source 610. The first reactant supply valve 630 is connected to the deposition controller 900 and may be controlled by the deposition controller 900.

The second reactant supply valve 640 may be opened or closed so that the reactant flowing through the reactant supply pipe 620 is supplied or not supplied to the deposition chamber 200. The second reactant supply valve 640 may be disposed in the reactant supply pipe 620 to be adjacent to the deposition chamber 200. The second reactant supply valve 640 is connected to the deposition controller 900 and may be controlled by the deposition controller 900.

The purge gas supply assembly 700 may supply a purge gas to the deposition chamber 200 for purging the interior of the deposition chamber 200. The purge gas supply assembly 700 may supply the purge gas to the deposition space SD of the deposition chamber 200. The purge gas may be an inert gas. For example, the purge gas may be argon gas. However, the purge gas is not limited thereto. The purge gas supply assembly 700 is connected to the deposition controller 900 and may be controlled by the deposition controller 900. The purge gas supply assembly 700 includes a purge gas supply source 710, a purge gas supply pipe 720, a purge gas supply valve 730, etc.

The purge gas supply source 710 may store the purge gas. The purge gas supply source 710 may be a storage container, a storage tank or the like in which the purge gas is stored. However, the purge gas supply source 710 is not limited thereto.

The purge gas supply pipe 720 may provide a passage through which the purge gas of the purge gas supply source 710 is supplied to the deposition chamber 200. In other words, the purge gas of the purge gas supply source 710 may flow through the purge gas supply pipe 720 and be supplied to the deposition chamber 200. The purge gas supply pipe 720 may be connected to the purge gas supply source 710 and the deposition chamber 200.

The purge gas supply valve 730 may be opened or closed so that the purge gas of the purge gas supply source 710 flows or does not flow to the purge gas supply pipe 720. In addition, the flow rate of the purge gas flowing from the purge gas supply source 710 to the purge gas supply pipe 720 may be adjusted by the purge gas supply valve 730. The purge gas supply valve 730 may be disposed in the purge gas supply pipe 720 to be adjacent to the purge gas supply source 710. The purge gas supply valve 730 is connected to the deposition controller 900 and may be controlled by the deposition controller 900.

The deposition controller 900 may control the deposition chamber 200, the heater 300, the precursor supply assembly 400, the carrier gas supply assembly 500, the reactant supply assembly 600, and the purge gas supply assembly 700.

The deposition controller 900 may control the vacuum pump VP connected to the deposition chamber 200 to adjust the vacuum pressure inside the deposition chamber 200. In other words, the deposition controller 900 may control the vacuum pump VP to control the vacuum pressure of the deposition space SD of the deposition chamber 200. The deposition controller 900 may control the vacuum pump VP so that the vacuum pressure inside the deposition chamber 200 becomes 759 Torr or less.

The deposition controller 900 may control the heater 300 to adjust the temperature of the substrate W. The deposition controller 900 may control the heater 300 so that the temperature of the substrate W becomes 250° C. or more and less than 500° C. Also, the TMD thin film may be deposited on the substrate W when the temperature of the substrate W is 250° C. or more and less than 500° C. If the temperature of the substrate W is less than 250° C., decomposition of the TMD precursor or reactant for synthesizing the TMD thin film may not occur. Also, a surface reaction may not occur in which the transition metal of the TMD precursor, from which the organic matter is decomposed, reacts with the surface of the substrate W and is bound to the surface of the substrate W, or the chalcogen of the reactant, from which the organic matter is decomposed, reacts with the transition metal bound to the surface of the substrate W and is bound to the transition metal. In other words, a surface reaction for depositing the TMD thin film on the substrate W may not occur. If the temperature of the substrate W is 500° C. or more, because a vacancy may occur in the TMD thin film deposited on the substrate W, the electrical characteristics of the TMD thin film may be degraded and the characteristics of a semiconductor element including the TMD thin film may be degraded.

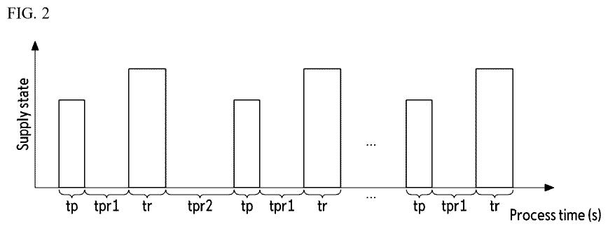

FIG. 2 is a graph showing a state in which the TMD precursor and the reactant are supplied to the deposition chamber according to the process time in the apparatus for depositing the TMD thin film of FIG. 1.

Referring to FIG. 2, the deposition controller 900 may control the precursor supply assembly 400 and the reactant supply assembly 600 such that the TMD precursor and the reactant are alternately supplied to the deposition chamber 200. The deposition controller 900 may control the second precursor supply valve 440 of the precursor supply assembly 400 and the second reactant supply valve 640 of the reactant supply assembly 600 such that the TMD precursor and the reactant are alternately supplied to the deposition chamber 200.

Because the TMD precursor and the reactant are alternately supplied to the deposition chamber 200, it is possible to prevent a gas phase nucleation reaction that occurs when the TMD precursor and the reactant are simultaneously supplied to the deposition chamber 200. In addition, it is possible to prevent particles from being generated on the surface of the TMD thin film due to the gas phase nucleation reaction. In addition, it is possible to prevent the particles generated on the surface of the TMD thin film from affecting the subsequent process.

Because the TMD precursor and the reactant are alternately supplied to the deposition chamber 200, the thermal energy supplied from the heater 300 to the substrate W may be concentrated on the decomposition of the TMD precursor and the binding of the transition metal to the substrate W due to the reaction of the transition metal of the TMD precursor from which the organic matter is decomposed, with the substrate W. In addition, the thermal energy supplied from the heater 300 to the substrate W may be concentrated on the decomposition of the reactant and the binding of the chalcogen to the transition metal due to the reaction of chalcogen of the reactant from which the organic matter is decomposed, with the transition metal bound to the substrate W. Further, the surface reaction in which the TMD thin film is deposited on the substrate W may be maximized. In addition, even if the temperature of the substrate W is 250° C. or more and less than 500° C., the TMD thin film deposited on the substrate W may have a crystalline layered structure.

A precursor supply time tp, which is the time during which the TMD precursor is supplied to the deposition chamber 200, and a reactant supply time tr, which is the time during which the reactant is supplied to the deposition chamber 200, may be 10 seconds or more. If the precursor supply time tp and the reactant supply time tr are each 10 seconds or more, the surface reaction for depositing the TMD thin film on the substrate W may be maximized. In addition, even if the temperature of the substrate W is 250° C. or more and less than 500° C., the TMD thin film deposited on the substrate W may have a crystalline layered structure. If the precursor supply time tp and the reactant supply time tr, which is the time during which the reactant is supplied to the deposition chamber 200, are less than 10 seconds, the surface reaction for depositing the TMD thin film on the substrate W may be insufficient. In addition, the TMD thin film deposited on the substrate W may not have a crystalline layered structure.

The precursor flow rate, which is the flow rate of the TMD precursor supplied from the precursor supply assembly 400, may be less than 6 sccm. In other words, the deposition controller 900 may control the precursor supply assembly 400 so that the precursor flow rate becomes less than 6 sccm. The deposition controller 900 may control the first precursor supply valve 430 of the precursor supply assembly 400 so that the precursor flow rate becomes less than 6 sccm.

A carrier gas flow rate, which is the flow rate of the carrier gas supplied to the precursor supply assembly 400, may be 1000 sccm or more. In other words, the deposition controller 900 may control the carrier gas supply assembly 500 so that the carrier gas flow rate becomes 1000 sccm or more. The deposition controller 900 may control the carrier gas supply valve 530 of the carrier gas supply assembly 500 so that the carrier gas flow rate becomes 1000 sccm or more.

In this way, because the precursor flow rate is less than 6 sccm and the carrier gas flow rate is 1000 sccm or more, the TMD precursor supplied at a low flow rate may be supplied to the deposition chamber 200 at a low concentration. Even if the temperature of the substrate W is 250° C. or more and less than 500° C., precursor seeding and thin film crystal growth induction for deposition of the TMD thin film onto the substrate W may be performed smoothly. The ratio of the precursor flow rate to the carrier gas flow rate may be smaller than 0.006. If the ratio of the precursor flow rate to the carrier gas flow rate is 0.006 or more, the precursor seeding and thin film crystal growth induction for deposition of the TMD thin film onto the substrate W may not be performed smoothly.

A reactant flow rate, which is the flow rate of the reactant supplied from the reactant supply assembly 600, may be equal to or greater than 40 times the precursor flow rate. In other words, the deposition controller 900 may control the reactant supply assembly 600 so that the reactant flow rate becomes equal to or greater than 40 times the precursor flow rate. The deposition controller 900 may control the first reactant supply valve 630 of the reactant supply assembly 600 so that the reactant flow rate becomes equal to or greater than 40 times the precursor flow rate. If the reactant supply flow rate becomes less than 40 times the precursor flow rate, the TMD thin film deposited on the substrate W may not have a crystalline layered structure.

Meanwhile, the deposition controller 900 may control the purge gas supply assembly 700 so that the interior of the deposition chamber 200 is purged by the purge gas for a first purge time tpr1 after the TMD precursor is supplied to the deposition chamber 200 for the precursor supply time tp. The deposition controller 900 may control the purge gas supply valve 730 of the purge gas supply assembly 700 so that the interior of the deposition chamber 200 is purged by the purge gas for a first purge time tpr1 after the TMD precursor is supplied to the deposition chamber 200.

By purging the interior of the deposition chamber 200 with the purge gas after the TMD precursor is supplied, the TMD precursor that was supplied to the deposition chamber 200 but was not used for depositing the TMD thin film onto the substrate W, the organic matter decomposed from the TMD precursor, or the like may be discharged from the deposition chamber 200. In addition, the TMD precursor or the like may not remain inside the deposition chamber 200. In addition, when the reactant is supplied to the deposition chamber 200 and the TMD thin film is deposited on the substrate W, a gas phase nucleation reaction between the reactant and the TMD precursor or the like remaining inside the deposition chamber 200 may be prevented. In addition, it is possible to prevent particles from being generated on the surface of the TMD thin film due to the gas phase nucleation reaction. In addition, it is possible to prevent particles generated on the surface of the TMD thin film from affecting subsequent processes.

The first purge time tpr1 may be equal to or greater than the precursor supply time tp and equal to or less than three times the precursor supply time tp. If the first purge time tpr1 is shorter than the precursor supply time tp, the interior of the deposition chamber 200 may not be sufficiently purged by the purge gas. In other words, even if the interior of the deposition chamber 200 is purged by the purge gas, the TMD precursor or the like may remain inside the deposition chamber 200. In addition, if the first purge time tpr1 is greater than three times the precursor supply time tp, the TMD thin film deposited on the substrate W may be sublimated.

The deposition controller 900 may control the purge gas supply assembly 700 so that the interior of the deposition chamber 200 is purged by the purge gas for a second purge time tpr2 after the reactant is supplied to the deposition chamber 200 for the reactant supply time tr. The deposition controller 900 may control the purge gas supply valve 730 of the purge gas supply assembly 700 so that the interior of the deposition chamber 200 is purged by the purge gas for the second purge time tpr2 after supplying the reactant to the deposition chamber 200.

By purging the interior of the deposition chamber 200 with the purge gas after supplying the reactant, the reactant that was supplied to the deposition chamber 200 but was not used for the TMD thin film deposition on the substrate W and the organic matter or the like decomposed from the reactant may be discharged. In addition, the reactant or the like may not remain inside the deposition chamber 200. In addition, when the TMD precursor is supplied to the deposition chamber 200 and the TMD thin film is deposited on the substrate W, a gas phase nucleation reaction due to the TMD precursor and reactant or the like remaining inside the deposition chamber 200 may be prevented. In addition, it is possible to prevent particles from being generated on the surface of the TMD thin film due to the gas phase nucleation reaction. In addition, it is possible to prevent particles generated on the surface of the TMD thin film from affecting subsequent processes.

The second purge time tpr2 may be equal to or greater than the reactant supply time tr and equal to or less than three times the reactant supply time tr. If the second purge time tpr2 is shorter than the reactant supply time tr, the interior of the deposition chamber 200 may not be sufficiently purged by the purge gas. In other words, even if the interior of the deposition chamber 200 is purged by the purge gas, reactant or the like may remain inside the deposition chamber 200. In addition, if the second purge time tpr2 is greater than three times the reactant supply time tr, the TMD thin film deposited on the substrate W may be sublimated.

The supply of the TMD precursor to the deposition chamber 200, purging of the interior of the deposition chamber 200 with a purge gas, supplying of the reactant to the deposition chamber 200, and purging of the interior of the deposition chamber 200 with a purge gas may be repeated in a cycle to deposit a TMD thin film on the substrate W in a crystalline layered structure.

The deposition controller 900 may be implemented in hardware, firmware, software, or any combination thereof. For example, the deposition controller 900 may be a computing device such as a workstation computer, a desktop computer, a laptop computer, a tablet computer, etc. For example, the deposition controller 900 may include a memory device, such as a read only memory (ROM) or a random access memory (RAM), and a processor configured to execute predetermined computations and algorithms, for example, a microprocessor, a central processing unit (CPU), a graphics processing unit (GPU), etc. In addition, the deposition controller 900 may include a receiver and a transmitter for receiving and transmitting electrical signals.

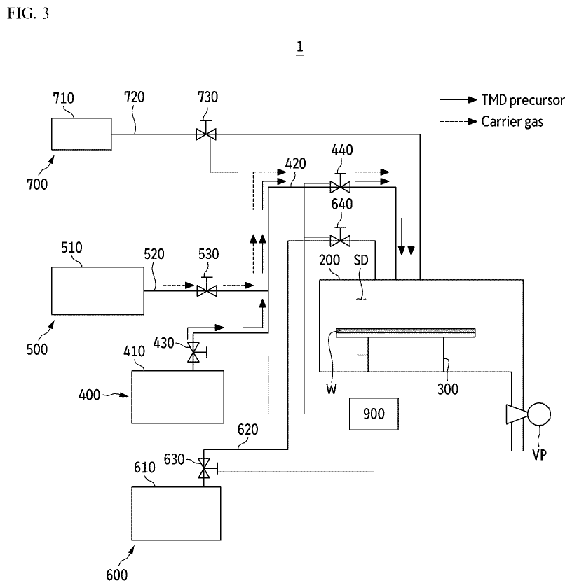

FIG. 3 is a diagram showing the supply of the TMD precursor to the deposition chamber in the apparatus for depositing a TMD thin film of FIG. 1.

Before the TMD precursor is supplied to the deposition chamber 200, the deposition controller 900 may control the heater 300 so that the temperature of the substrate W becomes equal to or higher than 250° C. and lower than 500° C. The deposition controller 900 may also control the vacuum pump VP so that the vacuum pressure inside the deposition chamber 200 becomes equal to or less than 759 Torr.

Referring to FIG. 3, the deposition controller 900 may open the first precursor supply valve 430 and the second precursor supply valve 440 of the precursor supply assembly 400. The deposition controller 900 may also control the first precursor supply valve 430 so that the precursor flow rate becomes less than 6 sccm. The deposition controller 900 may open the carrier gas supply valve 530 of the carrier gas supply assembly 500. The deposition controller 900 may also control the carrier gas supply valve 530 so that the carrier gas flow rate is greater than 1000 sccm.

By controlling the deposition controller 900 in this way, the TMD precursor of the precursor supply source 410 may flow into the precursor supply pipe 420. The carrier gas of the carrier gas supply source 510 may flow into the carrier gas supply pipe 520. The carrier gas flowing through the carrier gas supply pipe 520 may flow into the precursor supply pipe 420 and be mixed with the TMD precursor flowing through the precursor supply pipe 420. The TMD precursor and the carrier gas mixed in the precursor supply pipe 420 flow through the precursor supply pipe 420 and may be supplied to the deposition chamber 200. The TMD precursor and the carrier gas may be supplied to the deposition space SD of the deposition chamber 200.

While the TMD precursor supplied to the deposition chamber 200 together with the carrier gas moves to the substrate W, some of the organic matter may be decomposed by the thermal energy supplied to the substrate W from the heater 300. In addition, the transition metal of the TMD precursor from which some of the organic matter is decomposed may react with the surface of the substrate W and be bound to the surface of the substrate W. In addition, the TMD precursor which is not bound to the surface of the substrate W, the organic matter decomposed from the TMD precursor, and the like may be discharged from the deposition chamber 200 through a vacuum pump VP.

Meanwhile, an inert gas such as argon gas and hydrogen gas may be supplied to the deposition chamber 200 together with the TMD precursor by a separate gas supply assembly (not shown). The inert gas supplied to the deposition chamber 200 together with the TMD precursor may maintain the pressure inside the deposition chamber 200. In addition, hydrogen gas supplied to the deposition chamber 200 together with the TMD precursor may assist a TMD thin film growth on the substrate W by the TMD precursor.

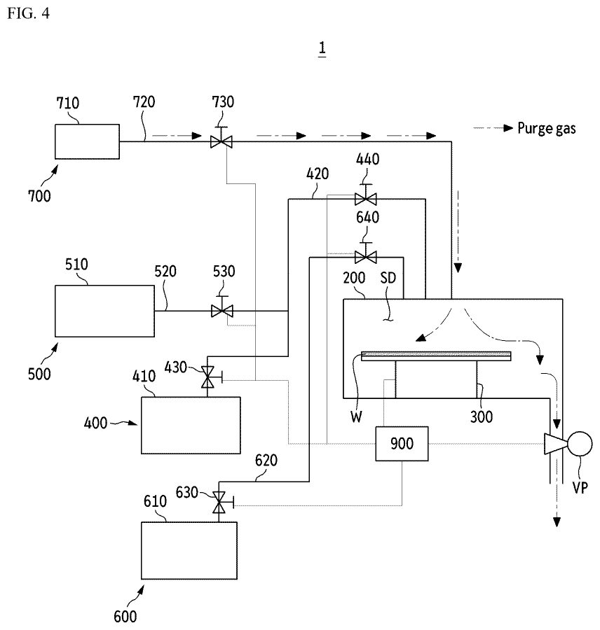

FIG. 4 is a diagram showing the process of purging the interior of the deposition chamber with a purge gas after the TMD precursor is supplied to the deposition chamber in the apparatus for depositing a TMD thin film of FIG. 1.

Referring to FIG. 4, after the TMD precursor is supplied to the deposition chamber 200 together with the carrier gas for the precursor supply time tp, the deposition controller 900 may close the first precursor supply valve 430 and the second precursor supply valve 440 of the precursor supply assembly 400 and the carrier gas supply valve 530 of the carrier gas supply assembly 500. The deposition controller 900 may also open the purge gas supply valve 730 of the purge gas supply assembly 700. The deposition controller 900 may also control the purge gas supply valve 730 to adjust the flow rate of the purge gas that flows from the purge gas supply source 710 of the purge gas supply assembly 700 to the purge gas supply pipe 720.

By controlling the deposition controller 900 in this way, the purge gas of the purge gas supply source 710 may flow into the purge gas supply pipe 720. The purge gas flowing through the purge gas supply pipe 720 may be supplied to the deposition chamber 200. The purge gas may be supplied to the deposition space SD of the deposition chamber 200.

The purge gas supplied to the deposition chamber 200 may purge the TMD precursors that are not bound to the surface of the substrate W remaining inside the deposition chamber 200, and the organic matter decomposed from the TMD precursor, the carrier gas or the like, from inside the deposition chamber 200. In other words, the TMD precursors that are not bound to the surface of the substrate W remaining inside the deposition chamber 200, or the like may be discharged from the deposition chamber 200 together with the purge gas through the vacuum pump VP.

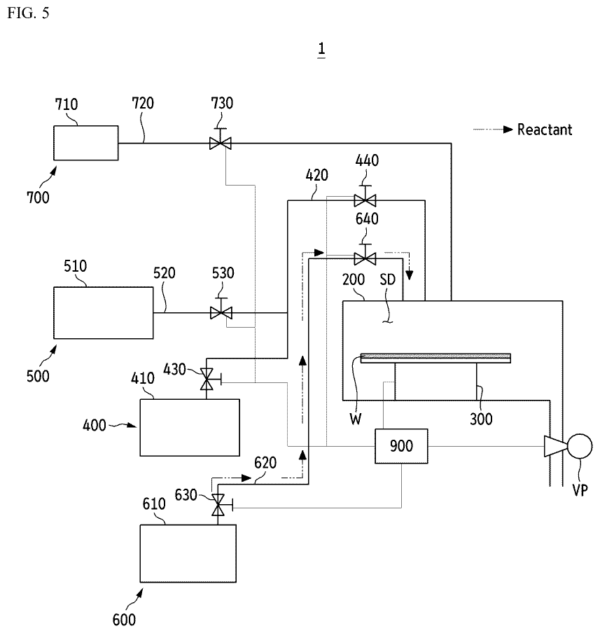

FIG. 5 is a diagram showing the supply of reactants to the deposition chamber in the apparatus for depositing a TMD thin film of FIG. 1.

Referring to FIG. 5, after the interior of the deposition chamber 200 is purged by the purge gas for the first purge time tpr1, the deposition controller 900 may close the purge gas supply valve 730 of the purge gas supply assembly 700. Also, the deposition controller 900 may open the first reactant supply valve 630 and the second reactant supply valve 640 of the reactant supply assembly 600. Also, the deposition controller 900 may control the first reactant supply valve 630 so that the reactant flow rate becomes equal to or greater than 40 times the precursor flow rate.

By controlling the deposition controller 900 in this way, the reactant of the reactant supply source 610 may flow to the reactant supply pipe 620. The reactant flowing through the reactant supply pipe 620 may be supplied to the deposition chamber 200. The reactant may be supplied to the deposition space SD of the deposition chamber 200.

While the reactant supplied to the deposition chamber 200 moves to the substrate W, some organic matter may be decomposed from the reactant by the thermal energy supplied to the substrate W from the heater 300. The organic matter may also be decomposed from the transition metal bound to the surface of the substrate W. Further, chalcogen of the reactant from which some organic matter is decomposed reacts with the transition metal bound to the surface of the substrate W and may be bound to the transition metal. Also, reactants that are not bound to the transition metal bound to the surface of the substrate W and organic matter decomposed from the reactants or the like may be discharged from the deposition chamber 200 through the vacuum pump VP.

Meanwhile, an inert gas such as argon gas and hydrogen gas may be supplied to the deposition chamber 200 together with the reactants by a separate gas supply assembly (not shown). The inert gas supplied to the deposition chamber 200 together with the reactants may maintain the pressure in the deposition chamber 200. Also, the hydrogen gas supplied to the deposition chamber 200 together with the reactants may assist a TMD thin film growth on the substrate W by the reactants.

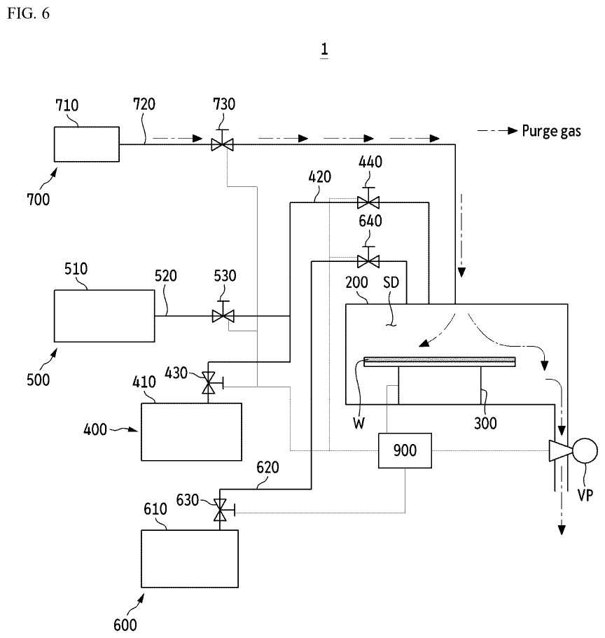

FIG. 6 is a diagram showing purging of the interior of the deposition chamber with a purge gas after supplying the reactants to the deposition chamber in the apparatus for depositing a TMD thin film of FIG. 1.

Referring to FIG. 6, after the reactants are supplied to the deposition chamber 200 for the reactant supply time tr, the deposition controller 900 may close the first reactant supply valve 630 and the second reactant supply valve 640 of the reactant supply assembly 600. Also, the deposition controller 900 may open the purge gas supply valve 730 of the purge gas supply assembly 700. The deposition controller 900 may control the purge gas supply valve 730 of the purge gas supply assembly 700 to adjust the flow rate of the purge gas that flows from the purge gas supply source 710 of the purge gas supply assembly 700 to the purge gas supply pipe 720.

By controlling the deposition controller 900 in this way, the purge gas of the purge gas supply source 710 may flow to the purge gas supply pipe 720. The purge gas flowing through the purge gas supply pipe 720 may be supplied to the deposition chamber 200. The purge gas may be supplied to the deposition space SD of the deposition chamber 200.

The purge gas supplied to the deposition chamber 200 may purge reactants that are not bound to the transition metal bound to the surface of the substrate W and organic matter decomposed from the reactants and the like, which remain inside the deposition chamber 200, from inside the deposition chamber 200. That is to say, reactants that are not bound to the transition metal bound to the surface of the substrate W and organic matter decomposed from the reactants and the like which remain inside the deposition chamber 200 may be discharged from the deposition chamber 200 through the vacuum pump VP together with the purge gas.

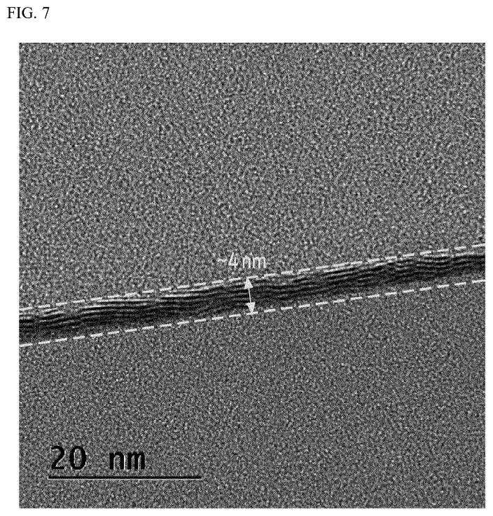

FIG. 7 is a transmission electron microscope (TEM) photograph of a cross section of an example of a TMD thin film deposited on the substrate by the apparatus for depositing a TMD thin film of FIG. 1.

An example of the TMD thin film deposited on the substrate by the apparatus 1 for depositing the TMD thin film uses molybdenum hexacarbonyl as a TMD precursor and diethyl sulfide as the reactant. The vacuum pressure inside the deposition chamber 200 is 1 Torr, and the temperature of the substrate W is set to 400° C. to 420° C. The precursor supply time tp was 10 seconds, the reactant supply time tr was 15 seconds, the first purge time tpr1 was 20 seconds, and the second purge time tpr2 was 30 seconds. The TMD precursor flow rate was 5.8 sccm, the carrier gas flow rate was 1000 sccm, and the reactant flow rate was 250 sccm.

Referring to FIG. 7, it may be seen that an example of the TMD thin film deposited on the substrate W by the apparatus 1 for depositing the TMD thin film has a crystalline layered structure.

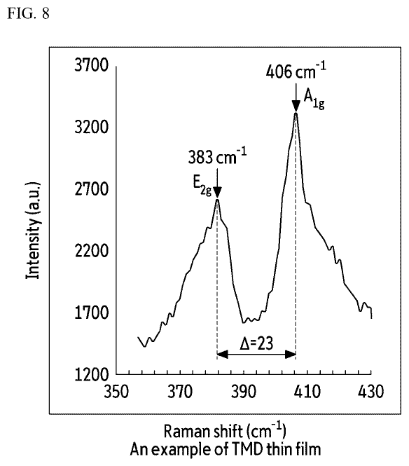

FIG. 8 is a graph showing results of Raman analysis of an example of the TMD thin film deposited on the substrate W by the apparatus for depositing a TMD thin film of FIG. 1.

The Raman spectrum of the molybdenum disulfide (MoS₂) thin film is made up of two regions, a region E_{2g} with Raman frequencies between 383 and 385 cm⁻¹ and a region A_{1g} with Raman frequencies between 405 and 407 cm⁻¹. At this time, the Raman frequency regions E_{2g} and A_{1g} refer to an in-plane vibration mode and an out-plane vibration mode, respectively. In addition, generally, when the Raman frequency difference between the region E_{2g} and the region A_{1g} is 20 cm⁻¹, it is close to a single-layer thin film, and as the Raman frequency difference is closer to 25 cm⁻¹, it may be interpreted as a multi-layer thin film.

Referring to FIG. 8, as the Raman analysis result of an example of the TMD thin film deposited on the substrate W by the apparatus 1 for depositing the TMD thin film, the Raman frequency is made up of two regions, which include the region E_{2g} with a Raman frequency of 383 to 385 cm⁻¹ and the region A_{1g} with a Raman frequency of 405 to 407 cm⁻¹, and the Raman frequency difference is 23 cm⁻¹. As a result, it may be seen that the example of the TMD thin film deposited on the substrate W by the apparatus 1 for depositing the TMD thin film is a multi-layer thin film of molybdenum disulfide. In other words, it may be seen that the example of the TMD thin film deposited on the substrate W by the apparatus 1 for depositing the TMD thin film has a layered structure.

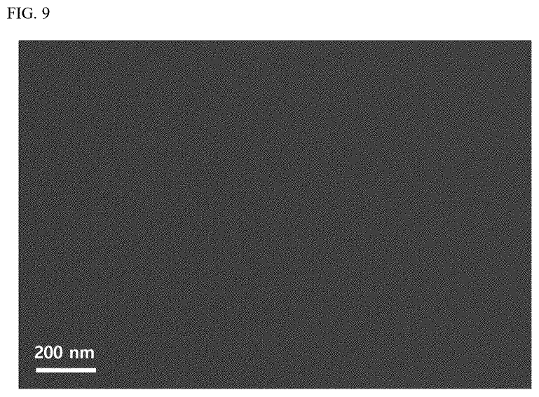

FIG. 9 is a scanning electron microscope (SEM) photograph of an example of the TMD thin film deposited on the substrate by the apparatus for depositing the TMD thin film of FIG. 1.

Referring to FIG. 9, it may be seen that no particles are generated on the surface of the example of the TMD thin film deposited on the substrate W by the apparatus 1 for depositing the TMD thin film.

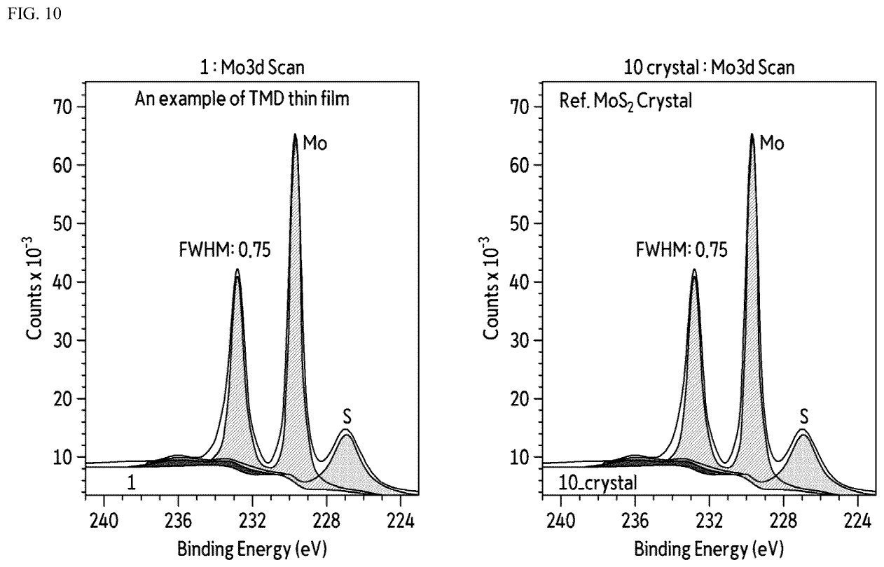

FIG. 10 is an X-ray photoelectron spectroscopy graph of an example of the TMD thin film deposited on the substrate W by the apparatus for depositing a TMD thin film of FIG. 1 and an X-ray photoelectron spectroscopy graph of molybdenum disulfide crystal (MoS₂ Crystal).

Referring to FIG. 10, it may be seen that an example of the TMD thin film deposited on the substrate W by the apparatus 1 for depositing the TMD thin film is a molybdenum disulfide crystal. In other words, it may be seen that an example of the TMD thin film deposited on the substrate W by the apparatus 1 for depositing the TMD thin film is crystalline.

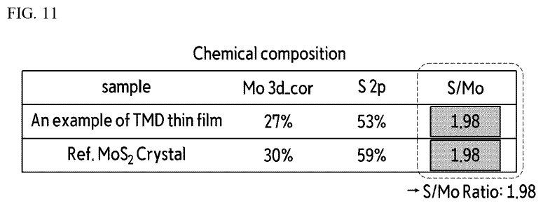

FIG. 11 is a table showing a ratio of molybdenum and sulfur of an example of the TMD thin film deposited on the substrate by the apparatus for depositing the TMD thin film of FIG. 1 and a ratio of molybdenum and sulfur of the molybdenum disulfide crystal (MoS₂ Crystal).

Referring to FIG. 11, it may be seen that the ratio of molybdenum and sulfur of an example of the TMD thin film deposited on the substrate W by the apparatus 1 for depositing the TMD thin film is 1:1.98 and is the same as the 1:1.98 ratio which is the ratio of molybdenum and sulfur of the molybdenum disulfide crystal. This shows that no vacancy was generated in an example of the TMD thin film deposited on the substrate W by the apparatus 1 for depositing the TMD thin film.

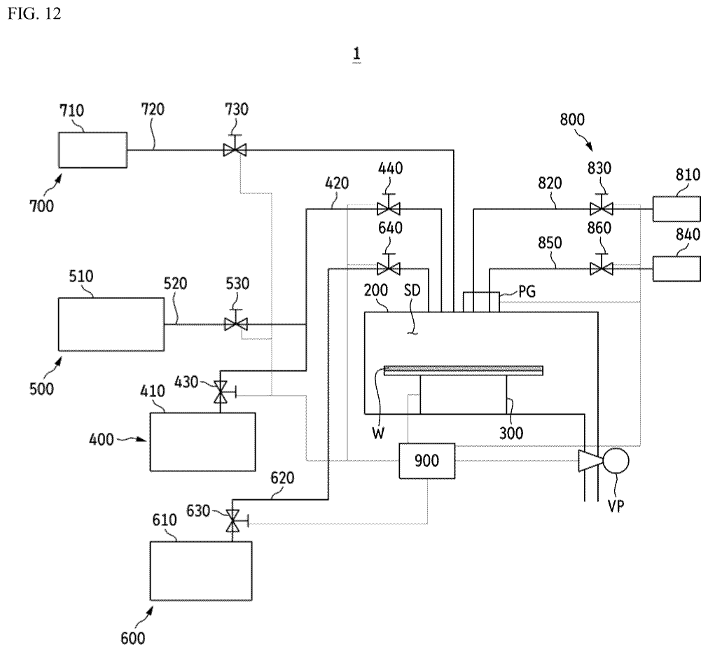

FIG. 12 is a diagram showing the apparatus for depositing the TMD thin film according to some embodiments of the present disclosure. For convenience of explanation, differences from those described using FIGS. 1 to 11 will be mainly described.

Referring to FIG. 12, in the apparatus 1 for depositing the TMD thin film, the substrate W may be pretreated before the TMD thin film is deposited on the substrate W. Such a pretreatment of the substrate W may modify the surface of the substrate W to improve the bonding force of the surface of the substrate W. Pretreatment of the substrate W may modify the surface of the substrate W to increase dangling bonds on the surface of the substrate W. Also, the bonding force of the transition metal of the TMD precursor to the surface of the substrate W may be enhanced.

At the time of pretreatment of the substrate W, the deposition controller 900 may control the vacuum pump VP so that the vacuum pressure of the deposition chamber 200 is 1 Torr or less. If the vacuum pressure of the deposition chamber 200 is greater than 1 Torr at the time of the pretreatment of the substrate W, unintended radicals may be mixed at the time of the pretreatment of the substrate W, and the pretreatment of the substrate W may not be performed as desired.

At the time of the pretreatment of the substrate W, the deposition controller 900 may operate or not operate the heater 300.

The substrate W may be pretreated with a pretreatment gas in a plasma PL state. To this end, a plasma generator PG which turns the pretreatment gas into plasma PL and is controlled by the deposition controller 900 may be disposed in or connected to the deposition chamber 200. The plasma generator PG may turn the pretreatment gas into plasma by an ICP (Inductively Coupled Plasma) method, a CCP (Capacitively Coupled Plasma) method, a RPS (Remote Plasma Source) method, a surface plasma method, or the like. For example, the plasma generator PG may include an antenna which is connected to a power source and transmits RF (Radio Frequency) to the deposition chamber 200 to generate plasma. However, the plasma generator PG is not limited thereto.

For pretreatment of the substrate W with the pretreatment gas of the plasma PL state, the apparatus 1 for depositing the TMD thin film may further include a pretreatment gas supply assembly 800. The pretreatment gas supply assembly 800 may supply a pretreatment gas used to pretreat the substrate W. The pretreatment gas supply assembly 800 is connected to the deposition controller 900 and may be controlled by the deposition controller 900.

The pretreatment gas supply assembly 800 may supply a first pretreatment gas and a second pretreatment gas to the deposition chamber 200. The first pretreatment gas may be supplied to the deposition chamber 200 for plasma generation. The first pretreatment gas may be an inert gas. For example, the first pretreatment gas may be argon gas. However, the first pretreatment gas is not limited thereto. The second pretreatment gas may be supplied to the deposition chamber 200 for pretreatment of the substrate W. For example, the second pretreatment gas may be oxygen gas. The second pretreatment gas may be turned into plasma by the first pretreatment gas turned into plasma and the plasma generator PG. The second pretreatment gas may pretreat the substrate W in the plasma state.

The pretreatment gas supply assembly 800 includes a first pretreatment gas supply source 810, a first pretreatment gas supply pipe 820, a first pretreatment gas supply valve 830, a second pretreatment gas supply source 840, a second pretreatment gas supply pipe 850, a second pretreatment gas supply valve 860, etc.

The first pretreatment gas supply source 810 may store the first pretreatment gas. The first pretreatment gas supply source 810 may be a storage container or a storage tank in which the first pretreatment gas is stored. However, the first pretreatment gas supply source 810 is not limited thereto.

The first pretreatment gas supply pipe 820 may provide a passage through which the first pretreatment gas of the first pretreatment gas supply source 810 is supplied to the deposition chamber 200. In other words, the first pretreatment gas of the first pretreatment gas supply source 810 flows through the first pretreatment gas supply pipe 820 and may be supplied to the deposition chamber 200. The first pretreatment gas supply pipe 820 may be connected to the first pretreatment gas supply source 810 and the deposition chamber 200.

The first pretreatment gas supply valve 830 may be opened or closed so that the first pretreatment gas of the first pretreatment gas supply source 810 flows or does not flow to the first pretreatment gas supply pipe 820. In addition, the flow rate of the first pretreatment gas flowing from the first pretreatment gas supply source 810 to the first pretreatment gas supply pipe 820 may be adjusted by the first pretreatment gas supply valve 830. The first pretreatment gas supply valve 830 may be disposed in the first pretreatment gas supply pipe 820 to be adjacent to the first pretreatment gas supply source 810. The first pretreatment gas supply valve 830 is connected to the deposition controller 900 and may be controlled by the deposition controller 900.

The second pretreatment gas supply source 840 may store the second pretreatment gas. The second pretreatment gas supply source 840 may be a storage container or a storage tank in which the second pretreatment gas is stored. However, the second pretreatment gas supply source 840 is not limited thereto.

The second pretreatment gas supply pipe 850 may provide a passage through which the second pretreatment gas of the second pretreatment gas supply source 840 is supplied to the deposition chamber 200. In other words, the second pretreatment gas of the second pretreatment gas supply source 840 flows through the second pretreatment gas supply pipe 850 and may be supplied to the deposition chamber 200. The second pretreatment gas supply pipe 850 may be connected to the second pretreatment gas supply source 840 and the deposition chamber 200.

The second pretreatment gas supply valve 860 may be opened or closed so that the second pretreatment gas of the second pretreatment gas supply source 840 flows or does not flow to the second pretreatment gas supply pipe 850. In addition, the flow rate of the second pretreatment gas flowing from the second pretreatment gas supply source 840 to the second pretreatment gas supply pipe 850 may be adjusted by the second pretreatment gas supply valve 860. The second pretreatment gas supply valve 860 may be disposed in the second pretreatment gas supply pipe 850 to be adjacent to the second pretreatment gas supply source 840. The second pretreatment gas supply valve 860 is connected to the deposition controller 900 and may be controlled by the deposition controller 900.

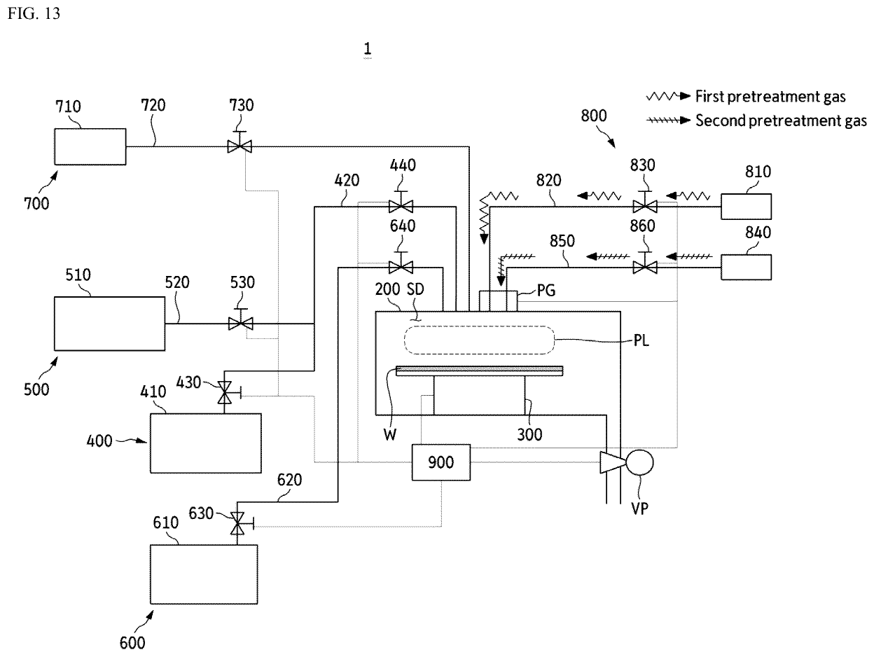

FIG. 13 is a diagram showing the pretreatment of a substrate in the apparatus for depositing the TMD thin film of FIG. 12.

Referring to FIG. 13, in order to pretreat the substrate W before depositing the TMD thin film on the substrate W, the deposition controller 900 may control the vacuum pump VP so that the vacuum pressure of the deposition chamber 200 becomes 1 Torr or less.

In addition, the deposition controller 900 may control the heater 300 so that the heater 300 is operated or not operated.

The deposition controller 900 may open the first pretreatment gas supply valve 830 of the pretreatment gas supply assembly 800. The deposition controller 900 may also control the first pretreatment gas supply valve 830 so that the first pretreatment gas flow rate, which is the flow rate of the first pretreatment gas flowing from the first pretreatment gas supply source 810 of the pretreatment gas supply assembly 800 to the first pretreatment gas supply pipe 820, is adjusted. For example, the first pretreatment gas flow rate may be 10 sccm or more and 500 sccm or less. The deposition controller 900 may also operate the plasma generator PG.

By controlling the deposition controller 900, the first pretreatment gas of the first pretreatment gas supply source 810 may flow into the first pretreatment gas supply pipe 820. The first pretreatment gas flowing through the first pretreatment gas supply pipe 820 may be supplied to the deposition chamber 200. The first pretreatment gas flowing through the first pretreatment gas supply pipe 820 may be supplied to the deposition space SD of the deposition chamber 200. The first pretreatment gas supplied to the deposition chamber 200 may be turned into plasma PL by the plasma generator PG.

After the first pretreatment gas supplied to the deposition chamber 200 is turned into plasma PL by the plasma generator PG, the deposition controller 900 may open the second pretreatment gas supply valve 860 of the pretreatment gas supply assembly 800. For example, within 20 seconds after the first pretreatment gas supplied to the deposition chamber 200 is turned into plasma PL by the plasma generator PG, the deposition controller 900 may open the second pretreatment gas supply valve 860. The deposition controller 900 may control the second pretreatment gas supply valve 860 so that the second pretreatment gas flow rate, which is the flow rate of the second pretreatment gas flowing from the second pretreatment gas supply source 840 of the pretreatment gas supply assembly 800 to the second pretreatment gas supply pipe 850, is adjusted. For example, the second pretreatment gas flow rate may be 10 sccm or more and 500 sccm or less. The second pretreatment gas flow rate may be equal to or greater than the first pretreatment gas flow rate and 5 times or less than the first pretreatment gas flow rate.

By controlling the deposition controller 900, the second pretreatment gas of the second pretreatment gas supply source 840 may flow to the second pretreatment gas supply pipe 850. The second pretreatment gas flowing through the second pretreatment gas supply pipe 850 may be supplied to the deposition chamber 200. The second pretreatment gas flowing through the second pretreatment gas supply pipe 850 may be supplied to the deposition space SD of the deposition chamber 200. The second pretreatment gas supplied to the deposition chamber 200 is turned into plasma PL, and in the plasma PL state, the second pretreatment gas may pretreat the substrate W. In the plasma PL state, the second pretreatment gas may modify the surface of the substrate W. Such a pretreatment of the substrate W may be performed for the pretreatment time. For example, the pretreatment time may be 10 minutes or less.

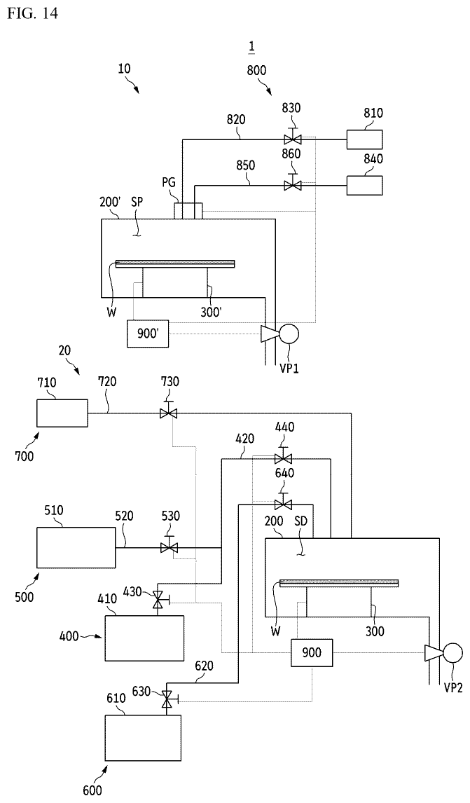

FIG. 14 is a diagram showing an apparatus for depositing a TMD thin film according to some embodiments of the present disclosure. For convenience of explanation, differences from the explanation using FIGS. 1 to 13 will be mainly explained.

Referring to FIG. 14, in the apparatus 1 for depositing the TMD thin film, the pretreatment of the substrate W and the deposition of the TMD thin film onto the substrate W may be performed separately. To this end, the apparatus 1 for depositing the TMD thin film includes a pretreatment assembly 10, a deposition assembly 20, etc.

The pretreatment assembly 10 may pretreat the substrate W. The pretreatment assembly 10 includes a pretreatment chamber 200′, a substrate support 300′, a pretreatment gas supply assembly 800, a pretreatment controller 900′, and the like.

The pretreatment chamber 200′ may provide a space for pretreatment of the substrate W. A pretreatment space SP is formed inside the pretreatment chamber 200′, and the substrate W may be pretreated in the pretreatment space SP.

A vacuum may be formed inside the pretreatment chamber 200′. In other words, the pretreatment space SP of the pretreatment chamber 200′ may be a vacuum. The pretreatment chamber 200′ may be connected to a first vacuum pump VP1 so that a vacuum is formed inside the pretreatment chamber 200′. The first vacuum pump VP1 may be connected to the pretreatment chamber 200′ to communicate with the pretreatment space SP of the pretreatment chamber 200′. The first vacuum pump VP1 discharges gases and the like of the pretreatment space SP to the outside of the pretreatment chamber 200′, and the pretreatment space SP becomes a vacuum. The first vacuum pump VP1 is connected to the pretreatment controller 900′ and may be controlled by the pretreatment controller 900′.

The substrate W may be pretreated by the pretreatment gas of the plasma PL state. In addition, a plasma generator PG which turns the pretreatment gas into plasma PL and is controlled by the pretreatment controller 900′ may be disposed in or connected to the pretreatment chamber 200′.

A gate (not shown) is formed in the pretreatment chamber 200′, and the substrate W may enter and exit the pretreatment space SP of the pretreatment chamber 200′ through the gate. In addition, a shower head (not shown) connected to the pretreatment gas supply assembly 800 may be disposed in the pretreatment chamber 200′. In addition, the first pretreatment gas and the second pretreatment gas supplied through the pretreatment gas supply assembly 800 may be evenly supplied to the pretreatment chamber 200′ through the shower head.

The substrate support 300′ may support the substrate W to be pretreated. The substrate support 300′ may be disposed inside the pretreatment chamber 200′. The substrate support 300′ may be disposed in the pretreatment space SP of the pretreatment chamber 200′. For example, the substrate support 300′ may be an electrostatic chuck or a heater. However, the substrate support 300′ is not limited thereto. The substrate support 300′ is connected to a pretreatment controller 900′ and may be controlled by the pretreatment controller 900′.

The pretreatment gas supply assembly 800 differs from the pretreatment gas supply assembly 800 described in FIG. 12 in that the former supplies the pretreatment gas to the pretreatment chamber 200′ and is controlled by the pretreatment controller 900′.

In other words, the first pretreatment gas supply pipe 820 of the pretreatment gas supply assembly 800 may be connected to the first pretreatment gas supply source 810 and the pretreatment chamber 200′. Also, the first pretreatment gas of the first pretreatment gas supply source 810 may be supplied to the pretreatment chamber 200′ through the first pretreatment gas supply pipe 820. The second pretreatment gas supply pipe 850 of the pretreatment gas supply assembly 800 may be connected to the second pretreatment gas supply source 840 and the pretreatment chamber 200′. The second pretreatment gas of the second pretreatment gas supply source 840 may be supplied to the pretreatment chamber 200′ through the second pretreatment gas supply pipe 850.

The pretreatment controller 900′ may control the pretreatment chamber 200′, the substrate support 300′, and the pretreatment gas supply assembly 800.

The pretreatment controller 900′ may control the first vacuum pump VP1 connected to the pretreatment chamber 200′ to adjust the vacuum pressure inside the pretreatment chamber 200′. In other words, the pretreatment controller 900′ may control the first vacuum pump VP1 to control the vacuum pressure of the pretreatment space SP of the pretreatment chamber 200′. The pretreatment controller 900′ may control the first vacuum pump VP1 so that the vacuum pressure of the pretreatment chamber 200′ becomes 1 Torr or less.

Furthermore, the pretreatment controller 900′ may control the plasma generator PG disposed or connected to the pretreatment chamber 200′.

The pretreatment controller 900′ may be implemented in hardware, firmware, software, or any combination thereof. For example, the pretreatment controller 900′ may be a computing device such as a workstation computer, a desktop computer, a laptop computer, a tablet computer, etc. For example, the pretreatment controller 900′ may include a memory device, such as a ROM (Read Only Memory) or a RAM (Random Access Memory), and a processor configured to execute predetermined computations and algorithms, for example, a microprocessor, a CPU (Central Processing Unit), a GPU (Graphics Processing Unit), etc. Furthermore, the pretreatment controller 900′ may include a receiver and a transmitter for receiving and transmitting electrical signals.

The pretreatment of the substrate W in the pretreatment assembly 10 under the control of the pretreatment controller 900′ may be the same as the pretreatment of the substrate W described referring to FIG. 13. Therefore, the description thereof will not be provided below.

The deposition assembly 20 may deposit a TMD thin film on the substrate W pretreated in the pretreatment assembly 10. The substrate W pretreated in the pretreatment assembly 10 may be transported to the deposition assembly 20 by a substrate transporter (not shown). The TMD thin film may be deposited on the substrate W transported from the pretreatment assembly 10 to the deposition assembly 20 in the deposition assembly 20.

The deposition assembly 20 differs from the configuration of the apparatus 1 for depositing the TMD thin film described referring to FIG. 1 only in that a second vacuum pump VP2 is connected to the deposition chamber 200 and the deposition controller 900 controls the second vacuum pump VP2 to form a vacuum inside the deposition chamber 200, and the remaining configurations may be the same. In addition, deposition of the TMD thin film on the substrate W in the deposition assembly 20 may be the same as deposition of the TMD thin film on the substrate W described referring to FIGS. 2 to 6. Therefore, the description thereof will not be provided below.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. An apparatus for depositing a transition metal dichalcogenide (TMD) thin film, comprising:
a deposition chamber in which a vacuum is configured to be formed;
a heater inside the deposition chamber, and configured to support and heat a substrate on which a TMD thin film is deposited;
a precursor supply assembly configured to supply a TMD precursor to the deposition chamber;
a reactant supply assembly configured to supply a reactant for synthesizing the TMD thin film together with the TMD precursor to the deposition chamber; and
a deposition controller configured to control:
the heater such that a temperature of the substrate becomes 250° C. or more and less than 500° C.; and
the precursor supply assembly and the reactant supply assembly such that the TMD precursor and the reactant are alternately supplied to the deposition chamber, and
wherein a precursor supply time, which is a time during which the TMD precursor is supplied to the deposition chamber, and a reactant supply time, which is a time during which the reactant is supplied to the deposition chamber, are each 10 seconds or more.

2. The apparatus for depositing the TMD thin film of claim 1, further comprising:
a purge gas supply assembly configured to supply a purge gas for purging an interior of the deposition chamber to the deposition chamber by control of the deposition controller,
wherein the deposition controller is configured to control the purge gas supply assembly such that the interior of the deposition chamber is purged by the purge gas for a first purge time, after the TMD precursor is supplied to the deposition chamber for the precursor supply time, and
wherein the deposition controller is configured to control the purge gas supply assembly such that the interior of the deposition chamber is purged by the purge gas for a second purge time, after the reactant is supplied to the deposition chamber for the reactant supply time.

3. The apparatus for depositing the TMD thin film of claim 2,
wherein the first purge time is equal to or greater than the precursor supply time and equal to or less than three times the precursor supply time, and
wherein the second purge time is equal to or greater than the reactant supply time and equal to or less than three times the reactant supply time.

4. The apparatus for depositing the TMD thin film of claim 1,
wherein a vacuum pump is connected to the deposition chamber, and
wherein the deposition controller is configured to control the vacuum pump such that a vacuum pressure inside the deposition chamber becomes 759 Torr or less.

5. The apparatus for depositing the TMD thin film of claim 1, further comprising:
a carrier gas supply assembly configured to supply a carrier gas for carrying the TMD precursor to the deposition chamber to the precursor supply assembly by control of the deposition controller.

6. The apparatus for depositing the TMD thin film of claim 5,
wherein a precursor flow rate, which is a flow rate of the TMD precursor supplied from the precursor supply assembly, is less than 6 sccm, and
wherein a carrier gas flow rate, which is a flow rate of the carrier gas supplied to the precursor supply assembly, is 1000 sccm or more.

7. The apparatus for depositing the TMD thin film of claim 5,
wherein the precursor supply assembly comprises a precursor supply pipe through which the TMD precursor is configured to flow and be connected to the deposition chamber,
wherein the carrier gas supply assembly comprises a carrier gas supply pipe through which the carrier gas is configured to flow, and
wherein the carrier gas supply pipe is connected to the precursor supply pipe, and the carrier gas flowing through the carrier gas supply pipe is configured to be supplied to the precursor supply pipe.

8. An apparatus for depositing a transition metal dichalcogenide (TMD) thin film, comprising:
a deposition chamber in which a vacuum is formed;
a heater inside the deposition chamber and configured to support and heat a substrate on which a TMD thin film is deposited;
a precursor supply assembly configured to supply a TMD precursor to the deposition chamber;
a reactant supply assembly configured to supply a reactant for synthesizing the TMD thin film together with the TMD precursor to the deposition chamber; and
a deposition controller configured to control:
the heater such that a temperature of the substrate becomes 250° C. or more and less than 500° C.,
the precursor supply assembly and the reactant supply assembly such that the TMD precursor and the reactant are alternately supplied to the deposition chamber,
wherein a precursor supply time, which is a time during which the TMD precursor is supplied to the deposition chamber, and a reactant supply time, which is a time during which the reactant is supplied to the deposition chamber, are each 10 seconds or more,
wherein the substrate is configured to be pretreated with a pretreatment gas in a plasma state before the TMD thin film is deposited, and
wherein a plasma generator configured to turn the pretreatment gas into a plasma by control of the deposition controller is disposed in or connected to the deposition chamber.

9. The apparatus for depositing the TMD thin film of claim 8, further comprising:
a pretreatment gas supply assembly configured to supply the pretreatment gas to the deposition chamber by control of the deposition controller.

10. The apparatus for depositing the TMD thin film of claim 9,
wherein the pretreatment gas supply assembly configured to supply a first pretreatment gas for generating plasma and a second pretreatment gas for pretreating the substrate in a plasma state to the deposition chamber.

11. The apparatus for depositing the TMD thin film of claim 10,
wherein the first pretreatment gas is an inert gas, and the second pretreatment gas is oxygen gas.

12. The apparatus for depositing the TMD thin film of claim 8,
wherein a vacuum pump is connected to the deposition chamber,
wherein the deposition controller is configured to control the vacuum pump such that a vacuum pressure inside the deposition chamber is 1 Torr or less at the time of pretreatment of the substrate, and
wherein the deposition controller is configured to control the vacuum pump such that a vacuum pressure inside the deposition chamber is 759 Torr or less at the time of deposition of the TMD thin film on the substrate.

13. The apparatus for depositing the TMD thin film of claim 8, further comprising:
a purge gas supply assembly configured to supply a purge gas for purging an interior of the deposition chamber to the deposition chamber by control of the deposition controller,
wherein the deposition controller is configured to control the purge gas supply assembly such that the interior of the deposition chamber is purged by the purge gas for a first purge time after the TMD precursor is supplied to the deposition chamber for the precursor supply time, and
wherein the deposition controller is configured to control the purge gas supply assembly such that the interior of the deposition chamber is purged by the purge gas for a second purge time after the reactant is supplied to the deposition chamber for the reactant supply time.

14. The apparatus for depositing the TMD thin film of claim 8, further comprising:
a carrier gas supply assembly configured to supply a carrier gas for carrying the TMD precursor to the deposition chamber to the precursor supply assembly by control of the deposition controller.

15. An apparatus for depositing a transition metal dichalcogenide (TMD) thin film, comprising:
a pretreatment assembly configured to pretreat a substrate; and
a deposition assembly configured to deposit a TMD thin film on the substrate pretreated in the pretreatment assembly,
wherein the pretreatment assembly comprises:
a pretreatment chamber in which a vacuum is formed;
a substrate support inside the pretreatment chamber and configured to support the substrate to be pretreated; and
a pretreatment controller configured to control the pretreatment chamber and the substrate support,
wherein the substrate is configured to be pretreated with a pretreatment gas in a plasma state, and
wherein a plasma generator configured to turn the pretreatment gas into plasma by control of the pretreatment controller is disposed in or connected to the pretreatment chamber,
wherein the deposition assembly comprises:
a deposition chamber in which a vacuum is formed;
a heater inside the deposition chamber and configured to support and heas a substrate on which the TMD thin film is deposited;
a precursor supply assembly which supplies a TMD precursor to the deposition chamber;
a reactant supply assembly configured to supply a reactant for synthesizing the TMD thin film together with the TMD precursor to the deposition chamber; and
a deposition controller configured to control:
the heater such that a temperature of the substrate becomes 250° C. or more and less than 500° C.,
the precursor supply assembly and the reactant supply assembly such that the TMD precursor and the reactant are alternately supplied to the deposition chamber, and
wherein a precursor supply time, which is a time during which the TMD precursor is supplied to the deposition chamber, and a reactant supply time, which is a time during which the reactant is supplied to the deposition chamber, are each 10 seconds or more.

16. The apparatus for depositing the TMD thin film of claim 15,
wherein the deposition assembly further comprises a purge gas supply assembly configured to supply a purge gas for purging an interior of the deposition chamber to the deposition chamber by control of the deposition controller,
wherein the deposition controller is configured to control the purge gas supply assembly such that the interior of the deposition chamber is purged by the purge gas for a first purge time after the TMD precursor is supplied to the deposition chamber for the TMD precursor supply time, and
wherein the deposition controller is configured to control the purge gas supply assembly such that the interior of the deposition chamber is purged by the purge gas for a second purge time after the reactant is supplied to the deposition chamber for the reactant supply time.

17. The apparatus for depositing the TMD thin film of claim 15,
wherein the deposition assembly further comprises a carrier gas supply assembly configured to supply a carrier gas for carrying the TMD precursor to the chamber to the precursor supply assembly by control of the deposition controller.

18. The apparatus for depositing the TMD thin film of claim 17,
wherein the precursor supply assembly comprises a precursor supply pipe through which the TMD precursor is configured to flow and be connected to the deposition chamber,
wherein the carrier gas supply assembly comprises a carrier gas supply pipe through which the carrier gas is configured to flow, and
wherein the carrier gas supply pipe is connected to the precursor supply pipe, and the carrier gas flowing through the carrier gas supply pipe is supplied to the precursor supply pipe.

19. The apparatus for depositing the TMD thin film of claim 15,
wherein the pretreatment assembly further comprise a pretreatment gas supply assembly configured to supply the pretreatment gas to the pretreatment chamber by control of the pretreatment controller.

20. The apparatus for depositing the TMD thin film of claim 19,
wherein the pretreatment gas supply assembly is configured to supply the deposition chamber with a first pretreatment gas for plasma generation and a second pretreatment gas for pretreating the substrate in a plasma state.
